(19) United States
(12) Patent Application Publication
(10) Pub. No.: US 2023/0345185 A1
(43) Pub. Date: Oct. 26, 2023

(54) MEMS MICROPHONE STRUCTURE AND MANUFACTURING METHOD THEREOF

(71) Applicant: DB HiTek Co., Ltd., Bucheon-si (KR)

(72) Inventor: Seok Young LEE, Yongin-si (KR)

(21) Appl. No.: 18/163,865

(22) Filed: Feb. 2, 2023

(30) Foreign Application Priority Data
Apr. 21, 2022 (KR) 10-2022-0049232

(51) Int. Cl. H04R 19/04; B81B 3/00; B81C 1/00; H04R 31/00; H04R 7/04; H04R 7/18; H04R 19/00

(52) U.S. Cl. CPC H04R 19/04; B81B 3/001; B81C 1/00968; H04R 31/006; H04R 31/003; H04R 7/04; H04R 7/18; H04R 19/005; B81B 2201/0257; B81B 2203/0127; B81B 2203/04; B81C 2201/0109; B81C 2201/013; H04R 2201/003

(57) ABSTRACT

Provided is a MEMS microphone structure (1) and, more particularly, to a MEMS microphone structure (1) that ensures excellent sensitivity by including and/or forming a lower electrode (410) and an upper electrode (430) with a diaphragm (110) in a bending area (A1) so that the maximum bending displacement of the diaphragm (110) is controlled by a dielectrophoretic (DFP) force together with sound pressure.

### CROSS REFERENCE TO RELATED APPLICATION

The present application claims priority to Korean Patent Application No. 10-2022-0049232, filed Apr. 21, 2022, the entire contents of which are incorporated herein for all purposes by this reference.

### BACKGROUND OF THE INVENTION

### Field of the Invention

The present disclosure relates to a MEMS microphone structure and, more particularly, to a MEMS microphone structure that ensures excellent sensitivity by including and/or forming a lower electrode and an upper electrode with a diaphragm in a bending area (e.g., of the MEMS microphone) so that the maximum bending displacement of the diaphragm is controlled by a dielectrophoretic (DEP) force together with sound pressure.

### DESCRIPTION OF THE RELATED ART

A microphone is a transducer that converts sound into an electrical signal, and types of microphones include, for example, dynamic, condenser, ribbon, and ceramic. The basic technology of microphones has greatly improved along with the development of electrical and electronic technology.

In particular, as the development of small wired and wireless devices accelerates, the size of the microphone is getting smaller. Recently, MEMS microphones using MEMS (micro-electro-mechanical systems) microfabrication technology have been developed. MEMS microphones may be classified into piezo and capacitive types. Among those two types, capacitive type MEMS microphones are mainly used because of the excellent frequency response characteristics in the voice band.

A MEMS microphone may include a bendable or flexible diaphragm and a backplate that faces the diaphragm. The diaphragm is spaced apart from a substrate and the backplate so as to freely bend up and down in response to acoustic pressure (e.g., sound). The diaphragm may include a membrane, and the diaphragm may be displaced by acoustic or sound pressure. That is, when the sound pressure reaches the diaphragm, the diaphragm bends upward and downward. The displacement of the diaphragm may be perceived through a value change in the capacitance between the diaphragm and the backplate, and as a result, sound may be converted into an electrical signal and output (e.g., by other structures in the MEMS microphone).

Referring to FIG. 1, a voltage level (Vp), which is the main characteristic of MEMS microphones, may generally be calculated by Equation (1):

Vp=2x*(k_{sys}/(1.5Cᵢₙₜ))\hat{ }(1/2) (1)

In Equation (1), x is the maximum displacement of a diaphragm 910, k_{sys} is the spring constant or the stiffness of the diaphragm in the MEMS microphone structure, and Cᵢₙₜ is the initial capacitance.

In order to increase the maximum displacement of the diaphragm 910, one may utilize a method of increasing the distance d between the diaphragm 910 and a backplate 930, or changing the characteristics of the diaphragm 910 to increase the magnitude of the stiffness value. Yet, such an increase in the separation distance d or a change in the characteristics of the diaphragm 910 is possible only by changing processing steps, which is problematic in that it affects the entire device.

Accordingly, the present disclosure proposes a novel and improved MEMS microphone structure and manufacturing method thereof in order to solve the above-mentioned problems, details of which will be described later.

### Document of Related Art

Korean Patent Application Publication No. 10-2018-0054288, entitled “MEMS MICROPHONE CHIP STRUCTURE AND MICROPHONE PACKAGE.”

### SUMMARY OF THE INVENTION

The present disclosure has been made to solve the problems of the related art, and an objective of the present disclosure is to provide a MEMS microphone structure and manufacturing method thereof for ensuring excellent sensitivity by forming and/or including a lower electrode and an upper electrode with a diaphragm in a bending area (e.g., of the MEMS microphone structure) so that the maximum bending displacement of the diaphragm is controlled by a dielectrophoretic (DEP) force together with sound pressure.

In addition, an objective of the present disclosure is to provide a MEMS microphone structure and manufacturing method thereof that electrically insulates the lower electrode from the diaphragm, and the upper electrode from the backplate by forming and/or including a first insulating film between the lower electrode and the diaphragm, and a second insulating film between the upper electrode and the backplate.

Moreover, an objective of the present disclosure is to provide a MEMS microphone structure and manufacturing method thereof for effectively preventing adhesion of the diaphragm to the upper electrode by including a projection on the upper insulating film, the projection having a height or vertical length greater than the sum of the thicknesses of the backplate, the second insulating film, and the upper electrode.

According to one or more embodiments of the present disclosure, there is provided a MEMS microphone structure, including a substrate having a cavity in a bending area (e.g., of the MEMS microphone structure); a diaphragm on, in or over the cavity in the bending area; an anchor on the substrate in a support area (e.g., of the MEMS microphone structure) and configured to support the diaphragm; a backplate spaced apart from the diaphragm (e.g., above the diaphragm); an upper insulating film on the backplate; a chamber on the substrate in the support area and configured to support the backplate; a lower electrode below the diaphragm; and an upper electrode between the diaphragm and the backplate.

According to another embodiment of the present disclosure, the upper electrode and the lower electrode may comprise a conductive material.

According to still another embodiment of the present disclosure, the MEMS microphone structure may further include a first insulating film having an upper surface in contact with the diaphragm and a lower surface in contact with the lower electrode; and a second insulating film having an upper surface in contact with the backplate and a lower surface in contact with the upper electrode.

According to still another embodiment of the present disclosure, the backplate, the second insulating film, and the upper electrode may include a plurality of projection holes at positions corresponding to each other (e.g., overlapping each other), and the upper insulating layer may include a plurality of projections passing through the respective projection holes in the backplate, the second insulating film, and the upper electrode.

According to still another embodiment of the present disclosure, each of the projections may have a length or height greater than a total thickness of the backplate, the second insulating film, and the upper electrode.

According to still another embodiment of the present disclosure, a MEMS microphone structure of the present disclosure may include a substrate having a cavity in a bending area (e.g., of the MEMS microphone structure); a diaphragm on, in or over the cavity in the bending area; an anchor on the substrate in a support area (e.g., of the MEMS microphone structure) and configured to support the diaphragm; a backplate spaced apart from the diaphragm (e.g., above the diaphragm), forming an air gap (e.g., between the backplate and the diaphragm); an upper insulating film on the backplate; a chamber on the substrate in the support area and configured to support the backplate; an upper electrode above the diaphragm; and a lower electrode below than the diaphragm (e.g., so as to sandwich the diaphragm), wherein the upper electrode and the lower electrode may be in the bending area.

According to still another embodiment of the present disclosure, the MEMS microphone structure may further include a first insulating film having an upper surface in contact with the diaphragm and a lower surface in contact with the lower electrode; and a second insulating film having an upper surface in contact with the backplate and a lower surface in contact with the upper electrode, wherein the diaphragm may include a plurality of vent holes spaced apart from each other, and the backplate and the upper insulating film may include a plurality of through holes spaced apart from each other.

According to still another embodiment of the present disclosure, the MEMS microphone structure may further include a lower insulating film on the substrate in a peripheral area (e.g., of the MEMS microphone structure); a diaphragm pad on the lower insulating film; a sacrificial layer on the lower insulating film; and a first electrode on the diaphragm pad and electrically connected to the diaphragm pad.

According to still another embodiment of the present disclosure, the MEMS microphone structure may further include a backplate pad on the sacrificial layer; and a second electrode on the backplate pad and electrically connected to the backplate pad.

According to still another embodiment of the present disclosure, the anchor may include a seating portion on the substrate in the support area; an inner wall extending from the seating portion; and an outer wall facing the inner wall and extending from the seating portion.

According to still another embodiment of the present disclosure, the backplate, the second insulating film, and the upper electrode may include a plurality of projection holes, at positions corresponding to each other (e.g., the holes in the backplate overlap the holes in the second insulating film and the upper electrode), and the upper insulating layer may include a plurality of projections passing through the respective projection through holes of the backplate, the second insulating film, and the upper electrode.

According to one or more embodiments of the present disclosure, there is provided a method of a MEMS microphone structure a MEMS microphone structure. The method includes forming a lower insulating film on a substrate; forming a lower electrode on the lower insulating film in a bending area (e.g., of the MEMS microphone structure); forming a first insulating film on the lower electrode; forming a diaphragm on the first insulating film; forming a sacrificial layer on the lower insulating film; forming an upper electrode on the sacrificial layer in the bending area; forming a second insulating film on the upper electrode; and forming a backplate on the second insulating film.

According to another embodiment of the present disclosure, forming the lower electrode and forming the first insulating film may include sequentially depositing a lower electrode layer and a first insulating layer on the lower insulating film; and etching the lower electrode layer and the first insulating layer outside the bending area.

According to still another embodiment of the present disclosure, forming the diaphragm may include forming an anchor groove in the lower insulating film in a support area (e.g., of the MEMS microphone structure); forming a first silicon layer on the lower insulating film, the lower electrode, and the first insulating film; doping the first silicon layer with impurities; and etching the first silicon layer to form the diaphragm and an anchor.

According to still another embodiment of the present disclosure, forming the upper electrode and forming the second insulating film may include sequentially depositing an upper electrode layer and a second insulating layer on the sacrificial layer; and etching the upper electrode layer and the second insulating layer outside the bending area.

According to still another embodiment of the present disclosure, forming the backplate may include forming a second silicon layer on the sacrificial layer, the second insulating film, and the upper electrode; doping the second silicon layer with impurities; and etching the second silicon layer to form the backplate and a backplate pad.

According to still another embodiment of the present disclosure, the manufacturing method may further include forming a cavity by etching the substrate in the bending area; and removing the lower insulating film over the cavity.

According to still another embodiment of the present disclosure, a method of manufacturing a MEMS microphone structure includes forming a lower insulating film on a substrate; forming a lower electrode on the lower insulating film and a first insulating film on the lower electrode in a bending area (e.g., of the MEMS microphone structure); forming a diaphragm on the first insulating film; forming a sacrificial layer on the lower insulating film; forming an upper electrode on the sacrificial layer in the bending area; forming a second insulating film on the upper electrode; forming a backplate on the second insulating film; forming first to third overlapping projection holes through the upper electrode, the second insulating film and the backplate, and forming recesses or depressions in the sacrificial layer under the first to third projection holes; and forming an upper insulating film having projections passing through the first to third projection holes on the backplate.

According to still another embodiment of the present disclosure, forming the upper insulating film may include forming a chamber region by etching the lower insulating film and the sacrificial layer; depositing an upper insulating layer on the sacrificial layer and in the chamber region; and forming the upper insulating film on the backplate and a chamber (e.g., in the support area) by etching the upper insulating layer.

The present disclosure has the following effects by one or more of the above configurations.

According to the present disclosure, excellent sensitivity can be ensured by including and/or forming a lower electrode and an upper electrode with a diaphragm therebetween in a bending area (e.g., of the MEMS microphone structure) so that the maximum bending displacement of the diaphragm is controlled by a dielectrophoretic (DFP) force together with sound pressure.

According to the present disclosure, the lower electrode and the diaphragm, and the upper electrode and a backplate can be electrically insulated by forming a first insulating film between the lower electrode and the diaphragm, and a second insulating film between the upper electrode and the backplate.

According to the present disclosure, adhesion of the diaphragm to the upper electrode can be effectively prevented by projections from an upper insulating film having a length greater than the sum of the thicknesses of the backplate, the second insulating film, and the upper electrode.

Meanwhile, it should be added that even if certain effects are not explicitly mentioned herein, the effects described in the following specification and/or expected by or flowing from the technical features of the present disclosure and their potential effects are treated as if they were described in the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic diagram for explaining calculation of a voltage level (Vp) in a conventional MEMS microphone;

FIG. 2 is a plan view of a MEMS microphone structure according to one or more embodiments of the present disclosure;

FIG. 3 is a cross-sectional view of the MEMS microphone structure of FIG. 2 taken along line A-A; and

FIGS. 4 to 21 are cross-sectional views showing various structures made during a method of manufacturing a MEMS microphone structure according to one or more embodiments of the present disclosure.

### DETAILED DESCRIPTION OF THE INVENTION

Hereinafter, embodiments of the present disclosure will be described in more detail with reference to the accompanying drawings. Embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those skilled in the art.

As used herein, the singular form may include the plural form, unless the context clearly indicates otherwise. In addition, as used herein, the terms “comprise” and/or “comprising” specify the presence of the recited shapes, numbers, steps, operations, members, elements, and/or groups thereof, but do not exclude the presence or addition of one or more other shapes, numbers, steps, operations, members, elements, and/or groups thereof.

Hereinafter, it should be noted that when one component (or layer) is described as being on another component (or layer), the one component may be directly on the other component, or one or more third components or layers may be between the components. In addition, when one component is expressed as being directly on or above another component, no additional components are between the one component and the other component. Moreover, being located on “top”, “upper”, “lower”, “top”, “bottom” or “one (first) side” or “side” of a component refers to a relative positional relationship.

Hereinafter, a MEMS microphone refers to a configuration or structure that converts sound into an electrical output signal by displacement or vibration of a diaphragm in response to sound pressure.

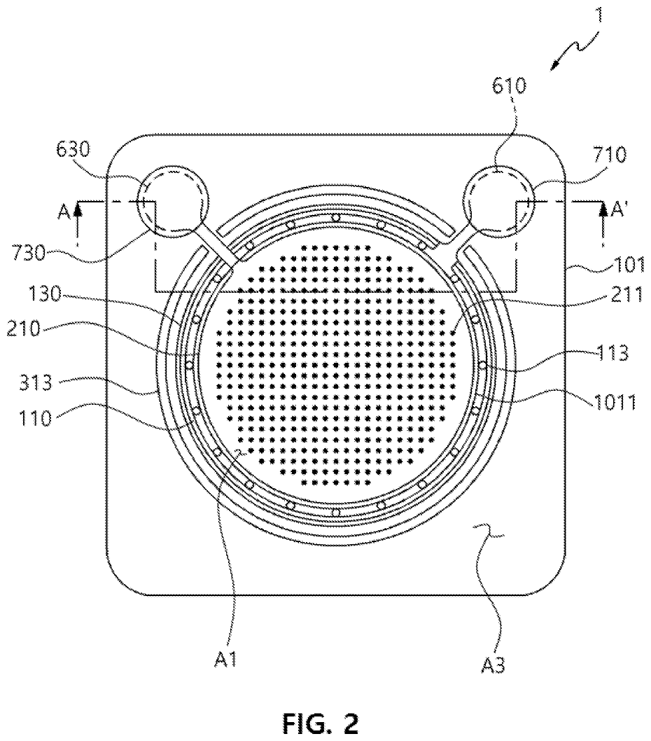

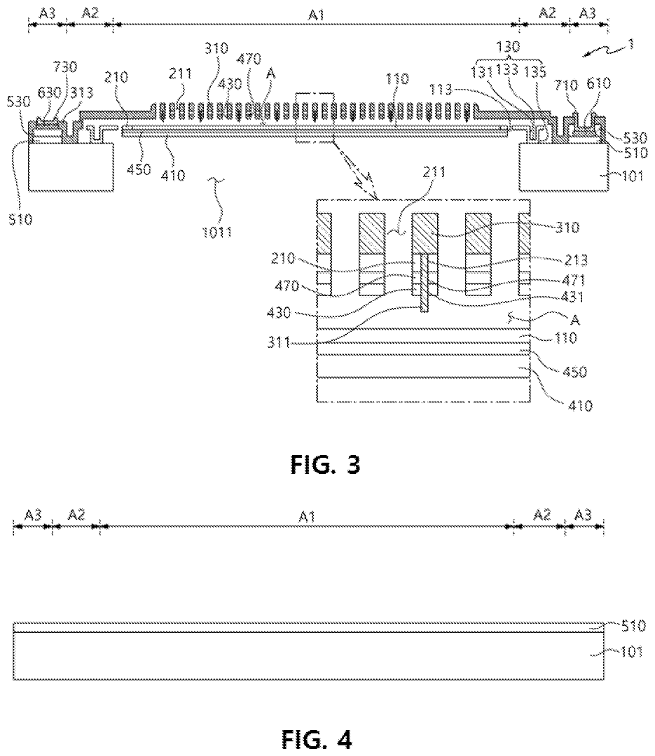

FIG. 2 is a plan view of a MEMS microphone structure according to one or more embodiments of the present disclosure, and FIG. 3 is a cross-sectional view of the MEMS microphone structure of FIG. 2 taken along line A-A′.

Hereinafter, a MEMS microphone structure 1 according to one or more embodiments of the present disclosure will be described in detail with reference to the accompanying drawings.

Referring to FIGS. 2 and 3, the present disclosure relates to a MEMS microphone structure 1 and, more particularly, to a MEMS microphone structure 1 that ensures excellent sensitivity by including a lower electrode 410, an upper electrode 430, and a diaphragm 110 therebetween in a bending area A1 (e.g., of the MEMS microphone), configured to enable control of the maximum bending displacement of the diaphragm 110 by a dielectrophoretic (DFP) force together (e.g., applied to at least one of the lower electrode 410 and the upper electrode 430) with sound pressure.

The MEMS microphone structure 1 may include a cavity 1011 defining a bending area A1; a chamber 313, an outermost wall of portion of which defines a support area A2 of the MEMS microphone structure 1, extending from the bending area A1; and a peripheral area A3 surrounding the support area A2. The support area A2 includes elements on a substrate 101 that support a diaphragm 110 and a backplate 210.

The cavity 1011 may be in the substrate 101 to prevent interference with the substrate 101 when the diaphragm 110 bends or vibrates due to sound pressure (which may optionally be affected by a dielectrophoretic force). The cavity 1011 is in the bending area A1, and may have a substantially circular and/or planar shape, but is not limited thereto.

In addition, the diaphragm 110 may be on or over the substrate 101. To be specific, the diaphragm 110 is on or over the substrate 101, in the bending area A1, and over the cavity 1011, and has a configuration in which displacement or vibration occurs by sound pressure and which may be affected by a dielectrophoretic force. The diaphragm 110 may cover the cavity 1011. The lower portion of the cavity 1011 (e.g., the opening of the cavity 1011 at the surface of the substrate 101 opposite from the diaphragm 110) may remain open, for example, to minimize reflections of sound or acoustic waves, but may also be covered directly or indirectly by circuit board or other mechanical substrate or a housing. The diaphragm 110 has a substantially circular and/or planar shape, and as shown in FIG. 3, is higher than the substrate 101 and does not overlap with the substrate 101 vertically, thereby preventing interference with displacement or vibration of the diaphragm 110. In addition, the diaphragm 110 (or a surface thereof facing the backplate 210) may be doped with impurities. The impurity doping may be performed by ion implantation.

The diaphragm 110 may include a vent hole 113 penetrating or passing through the diaphragm 110. The vent hole 113 is at or adjacent to the boundary between the diaphragm 110 and an anchor 130 to be described later, and a plurality of vent holes 113 may be spaced apart from each other along a circumference of the diaphragm 110, for example. The vent holes 113 may be a passage for air or sound pressure.

The anchor 130 may be at or along an end, periphery, or circumference of the diaphragm 110. The anchor 130 is on the substrate 101 and is configured to support the diaphragm 110 so that the diaphragm 110 covers and/or is suspended above the cavity 1011. The anchor 130 may have a ring and/or planar shape in a plan view and a substantially square or rectangular cross-section, and may be in the support area A2. The anchor 130 may include a seating portion 131 that is in contact with the substrate 101; an inner wall 133 extending upward and/or orthogonally from the seating portion 131 (e.g., as shown in FIG. 3); and an outer wall 135 facing the inner wall 133 and extending upward and/or orthogonally from the seating portion 131. The outer wall 135 may be to surround the inner wall 133. That is, the outer wall 135 may be adjacent and/or closer to the peripheral area A3, and the inner wall 133 may be adjacent and/or closer to the bending area A1. In this way, when the anchor 130 has a step or height difference between the seating portion 131 and the inner wall 133 and the outer wall 135, effective bending or vibration of the diaphragm 110 may be ensured.

The backplate 210 is above the diaphragm 110. That is, the backplate 210 may be vertically spaced apart from the diaphragm 110. The backplate 210 and the diaphragm 110 may face each other, and both may overlap the cavity 1011. The backplate 210 may also be in the bending area A1. In addition, the backplate 210 may have a circular and/or planar shape, and may include a region doped with impurities by, for example, ion implantation. The backplate 210 and the diaphragm 110 are connected to respective pads 610 and 630, and may function as electrodes.

An upper insulating film 310 may be on the backplate 210. The upper insulating film 310 covers the backplate 210, and may allow the backplate 210 to hang or be suspended at a position spaced apart from the diaphragm 110 by a predetermined distance. An air gap A may be between the backplate 210 and the diaphragm 110.

A plurality of through holes 211 may be in the backplate 210 and the upper insulating film 310, spaced apart from each other. The through hole 211 is a sound hole for passage of sound waves, and communicates with the air gap A. In addition, a plurality of projection through holes 213 may be in the backplate 210 separately from the through holes 211, and projections 311 may be formed through the projection through holes 213, respectively. The projection 311 is connected to and/or extending from the upper insulating film 310, and this is to prevent the diaphragm 110 from contacting and/or adhering to the backplate 210 when the diaphragm 110 bends or is displaced. To this end, the projection 311 has a length extending from the bottom of the backplate 210, so that when the diaphragm 110 bends to an extent at which it might contact the backplate 210, such contact (and the subsequent risk of adhesion to the backplate 210) is prevented, enabling the diaphragm 110 to return to its original position.

A chamber 313 may be at an end or circumference, or at or in a periphery, of the upper insulating film 310 so that the upper insulating film 310 is at a fixed position above the diaphragm 110. The chamber 313 is on the substrate 101, and sidewalls of the chamber 313 effectively raise and/or support the upper insulating film 310 and the backplate 210 apart from the diaphragm 110. The cross-sectional shape of the chamber 313 is not limited, but may be formed in a substantially “c” or “u” shape, for example. In addition, the chamber 313 may have, for example, a ring shape (e.g., in a plan or overhead view) and/or a plurality of planar or substantially planar surfaces (which may be parallel or substantially parallel to each other). The chamber 313 may be in the support area A2. That is, the support area A2 may include the anchor 130 and the chamber 313.

A lower electrode 410 may be below the diaphragm 110, and an upper electrode 430 may be below the backplate 210. That is, the diaphragm 110 may be between the lower electrode 410 and the upper electrode 430. The lower electrode 410 and the upper electrode 430 may comprise a conductive material such as a transparent conductive film (e.g., indium tin oxide [ITO]), tungsten (W), or aluminum (A1), but there is no special limitation thereto. A first insulating film 450 may be between the lower electrode 410 and the diaphragm 110 for electrical isolation of both components, and a second insulating film 470 may be between the upper electrode 430 and the backplate 210. The first insulating film 450 and the second insulating film 470 may comprise, for example, a silicon oxide (e.g., doped or undoped silicon dioxide) film or a nitride (e.g., silicon nitride) film. The lower electrode 410 and the upper electrode 430 may be in the bending area A1 overlapping the cavity 1011.

To be specific, the first insulating film 450 may be on the lower electrode 410, and the diaphragm 110 may be on the first insulating film 450, while the second insulating film 470 may be on the upper electrode 430, and the backplate 210 may be on the second insulating film 470.

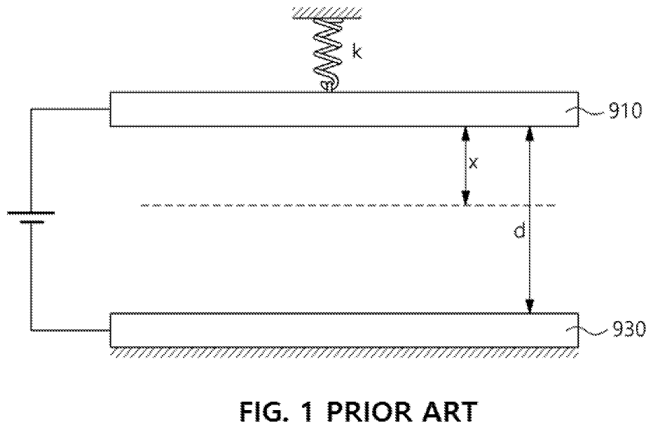

Referring to FIG. 1, a voltage level (Vp), which is a primary characteristic of MEMS microphones, may generally be calculated by Equation (1):

Vp=2x*(k_{sys}/(1.5Cᵢₙₜ))\hat{ }(1/2) (1)

In Equation (1), x is the maximum displacement of a diaphragm 910, k_{sys} is the spring constant or the stiffness of the MEMS microphone diaphragm, and Cᵢₙₜ is the initial capacitance (e.g., between the diaphragm and the backplate). In order to increase the maximum displacement (x) of the diaphragm 110 and thus improve the voltage level (Vp), one may utilize a method of increasing the distance d between the diaphragm 110 and the backplate 210 or changing the characteristics of the diaphragm 110 to increase the magnitude of the stiffness value. Yet, such an increase in the separation distance d or a change in the characteristics of the diaphragm 910 is possible only by changing materials and/or processing steps, which may adversely affect the entire device.

Accordingly, the present disclosure is intended to provide a structure capable of increasing the maximum bending displacement of the diaphragm 110 in order to improve the voltage level (Vp), which may be implemented with the lower electrode 410 and the upper electrode 430.

A material with permanent and/or induction dipoles may be subjected to a directional force along an electric field gradient in a non-uniform electric field, and the movement of the material by the force is called dielectrophoresis. The magnitude and direction of the dielectrophoretic force is affected by the permittivity and conductivity of the material and its surrounding medium in the electric field (e.g., air or a vacuum), as well as the frequency of the applied alternating electric field. The movement of the material may be precisely controlled by controlling the corresponding variables.

Thus, referring to FIG. 3, in the structure 1 according to one or more embodiments of the present disclosure, by applying wavelengths that vibrate hundreds of times per second or more with different magnitudes to the lower electrode 410 and the upper electrode 430 to form a non-uniform electric field around the electrodes 410 and 430, a dielectrophoretic force may be additionally applied to the diaphragm 110 by pulling or pushing the diaphragm 110 in one or more directions. As a result, it is possible to secure high sensitivity by increasing the maximum bending displacement of the diaphragm 110, and the stability of the present MEMS microphone device may be ensured by not otherwise changing the manufacturing process for those structures existing in prior MEMS microphone devices.

Projection holes 431 and 471 are in the upper electrode 430 and the second insulating film 470 at positions corresponding to the projection holes 213 in the backplate 210, and the projection 311 passes through all of the projection holes 213, 431, and 471. Thus, it is preferable that the projections 311 have a length greater than the total thickness of the upper electrode 410, the first insulating film 450 and the backplate 210.

A lower insulating film 510 may be on the substrate 101. One side or surface of the lower insulating film 510 may contact the upper surface of the substrate 101, and the lower insulating film 510 may be outside the anchor 130 and the chamber 313, that is, in the peripheral area A3. In addition, as shown in FIG. 3, the lower insulating film 510 is lower than the upper insulating film 310. The lower insulating film 510 may comprise silicon dioxide. A diaphragm pad 610 is on the lower insulating film 510. The diaphragm pad 610 is connected to the diaphragm 110, and may be doped with impurities by ion implantation.

A sacrificial layer 530 is on the lower insulating film 510. The sacrificial layer 530 may be in the peripheral area A3 outside the anchor 130 and the chamber 313. A backplate pad 630 is on the sacrificial layer 530. The backplate pad 630 is connected to the backplate 210, and may be doped with impurities by ion implantation similar to the diaphragm pad 610.

A first electrode 710 may be on the diaphragm pad 610, and a second electrode 730 may be on the backplate pad 630. The first electrode 710 may be electrically connected to the diaphragm pad 610, while the second electrode 730 may be electrically connected to the backplate pad 630.

FIGS. 4 to 21 are cross-sectional views showing a method of manufacturing a MEMS microphone structure according to one or more embodiments of the present disclosure.

Hereinafter, a method of manufacturing a MEMS microphone structure according to one or more embodiments of the present disclosure will be described in detail with reference to the accompanying drawings. Each step to be described may be performed differently in time from that described, and any plurality of steps may be performed substantially simultaneously, and there is no special limitation thereto.

First, referring to FIG. 4, a lower insulating film 510 is provided (e.g., by blanket deposition) on a substrate 101. The cavity 1011 is not yet formed in the bending area A1 of the substrate 101.

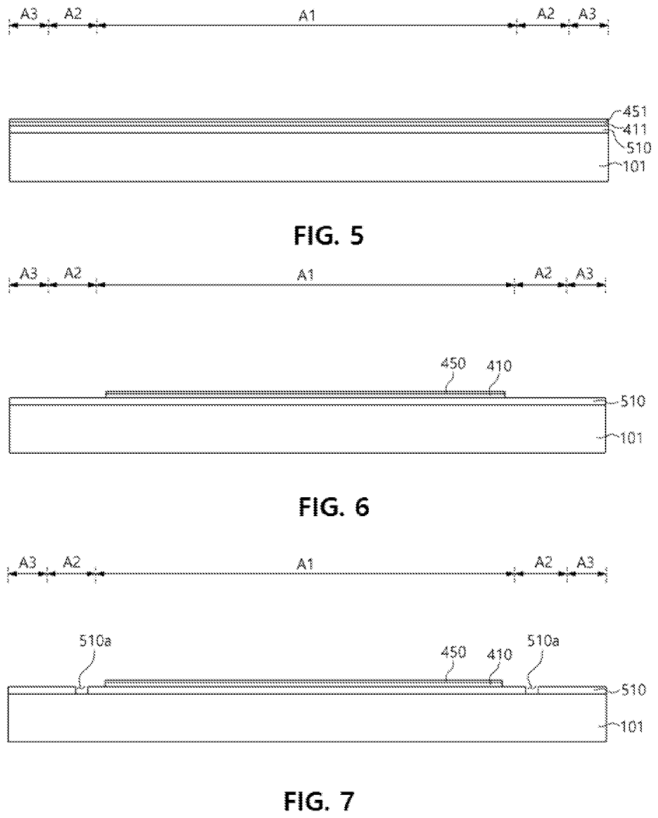

Then, as shown in FIG. 5, a lower electrode 410, a first insulating film 450, a diaphragm 110 and an anchor 130 are formed on the lower insulating film 510, which will be described in detail. After depositing a lower electrode layer 411 and a first insulating layer 451 on the lower insulating film 510, the layers 411 and 451 are photolithographically patterned and etched to form the lower electrode 410 and the first insulating film 450 as shown in FIG. 6.

Thereafter, referring to FIG. 7, in the lower insulating film 510 deposited on the substrate 101, an anchor groove 510a having a complementary shape to a seating portion 131, an inner wall 133, and an outer wall 135 of the anchor 130 is formed. One side of the substrate 101 may be exposed by the anchor groove 510a. In addition, the anchor groove 510a has, for example, a ring shape and may be formed in the support area A2. Alternatively, the anchor groove 510a may be formed before the lower electrode 410 and the first insulating film 450 are formed, but there is no limitation thereto.

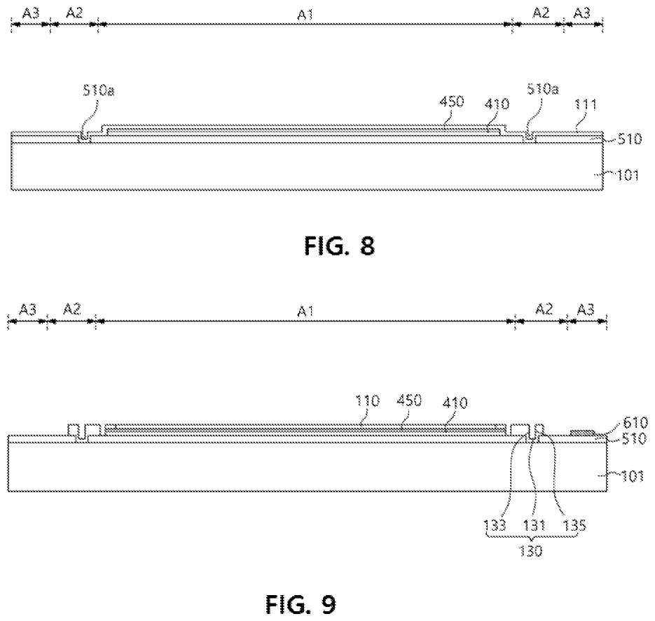

Thereafter, referring to FIG. 8, a first silicon layer 111 is blanket-deposited and/or conformally deposited on the lower insulating film 510, the first insulating film 450 and the lower electrode 410. The first silicon layer 111 may surround and fill the anchor groove 510a. The first silicon layer 111 may comprise, for example, a polysilicon layer.

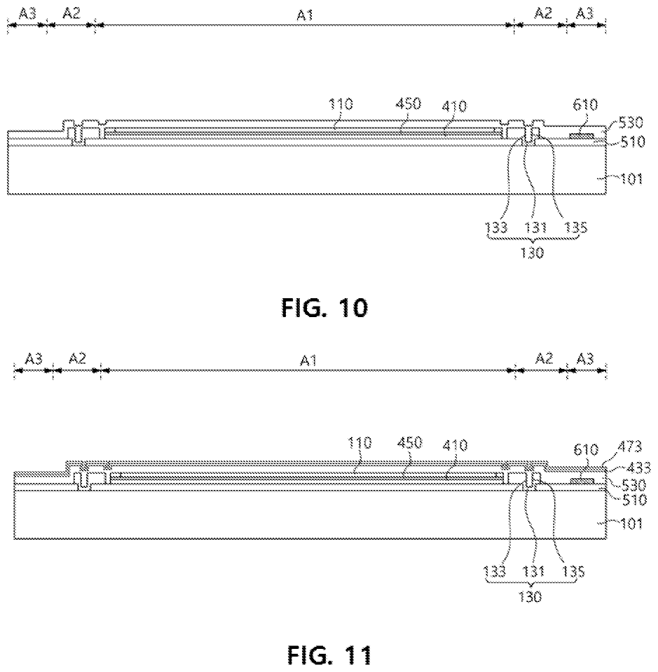

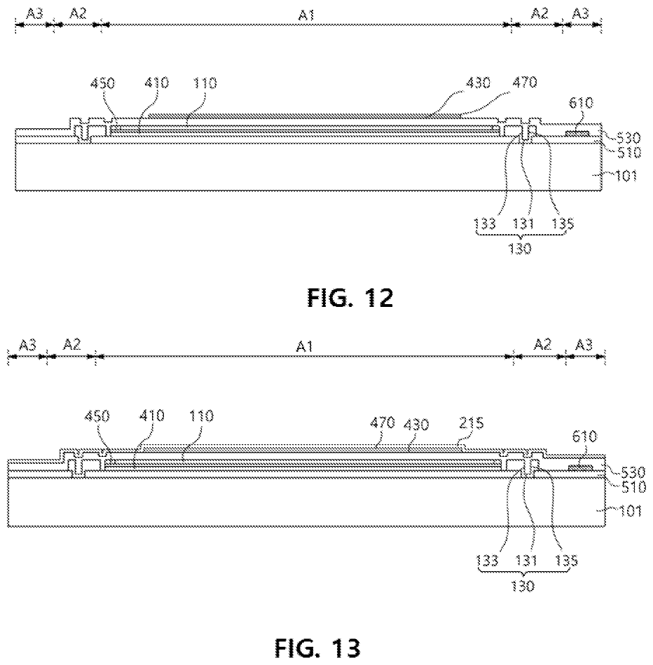

Then, part or all of the first silicon layer 111 is doped with impurities, which may be performed by ion implantation (with or without a photolithographically-patterned mask to block implantation in predetermined areas of the first silicon layer 111). The impurity-doped region of the first silicon layer 111 may correspond to a region where the cavity 1011 is to be formed and/or to the diaphragm pad 610. Thereafter, referring to FIG. 9, the first silicon layer 111 may be etched to form the diaphragm 110, the anchor 130 and the diaphragm pad 610. One or more vent holes 113 may be formed in the diaphragm 110 (e.g., by photolithographic patterning and selective etching of the first silicon layer 111). Thereafter, referring to FIG. 10, a sacrificial layer 530 is blanket- and/or conformally deposited on the lower insulating film 510. The sacrificial layer 530 may comprise a material that is selectively etched relative to silicon, such as silicon dioxide formed from tetraethyl orthosilicate (TEOS), silicon nitride, etc. Then, an upper electrode 430 and a second insulating film 470 are formed on the sacrificial layer 530. For example, referring to FIG. 11, an upper electrode layer 433 and a second insulating layer 473 are sequentially blanket- and/or conformally deposited on the sacrificial layer 530. In addition, referring to FIG. 12, the upper electrode 430 and the second insulating film 470 may be formed by photolithographically patterning and etching the layers 433 and 473.

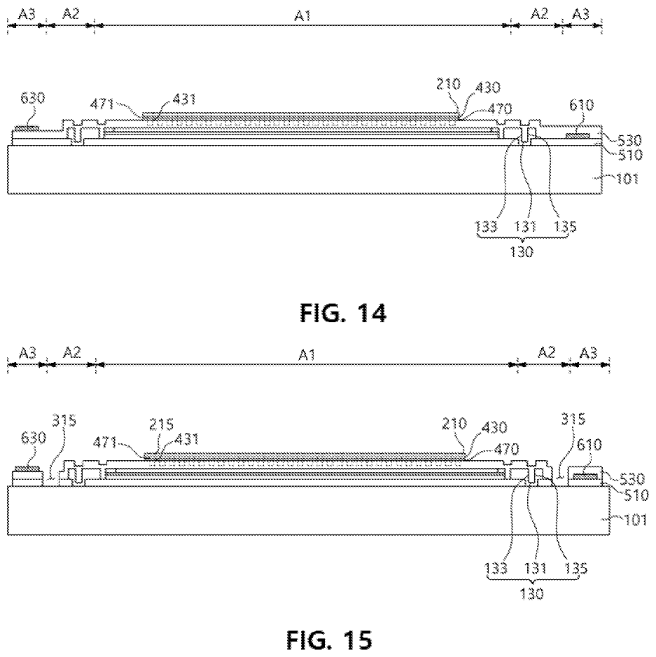

Then, a backplate 210 is formed, which will be described in detail. Referring to FIG. 13, first, a second silicon layer 215 is blanket-deposited on the sacrificial layer 530, the second insulating film 470 and the upper electrode 430. After that, impurities are implanted into the second silicon layer 215 by ion implantation. The second silicon layer 215 may comprise, for example, a polysilicon layer. Then, referring to FIG. 14, the backplate 210 and the backplate pad 630 may be formed by photolithographically patterning and etching the second silicon layer 215.

At this time, projection through holes 213, 431, and 471 may be formed in the upper electrode 430, the second insulating film 470, and the backplate 210, and the sacrificial layer 530 thereunder may be partially etched to form recesses or depressions into which the projections 311 are to be deposited.

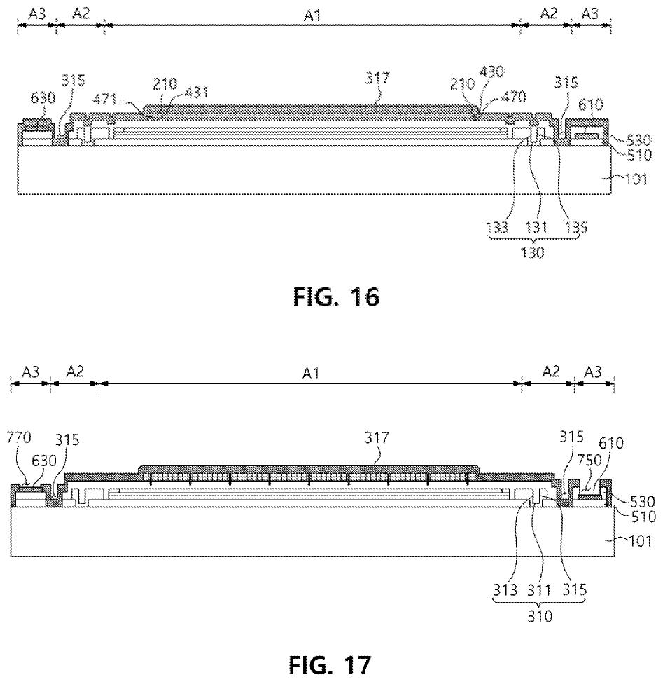

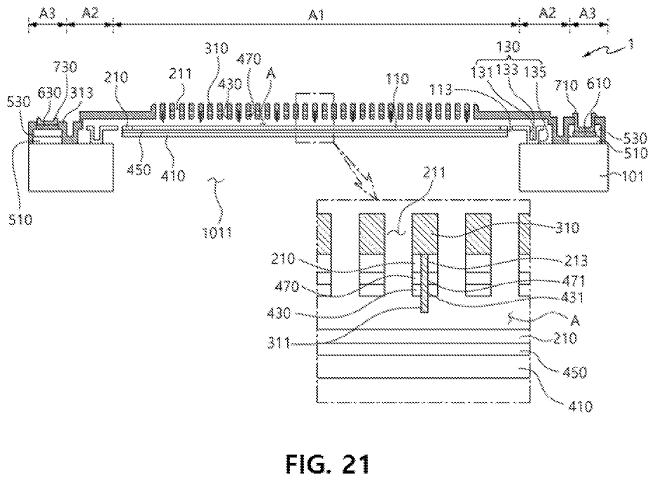

Thereafter, an upper insulating film 310 and a chamber 313 are formed, which will be described in detail. Referring to FIG. 15, first, a chamber region or gap 315 is formed by photolithographically patterning and etching the lower insulating film 510 and the sacrificial layer 530 in the region where the chamber 313 is to be formed. The substrate 101 may be exposed through the chamber region or gap 315. Thereafter, referring to FIG. 16, an upper insulating layer 317 is blanket- and/or conformally deposited on the sacrificial layer 530 and in the chamber region 315. Then, referring to FIG. 17, the upper insulating film 310 and the chamber 313 may be formed by photolithographic patterning and etching. During the deposition process of the upper insulating layer 317, the upper insulating layer 317 may fill the projection holes 213, 431, and 471 and the recesses or depressions in the sacrificial layer 530 to form a plurality of projections 311 (not shown in FIGS. 16-17; see FIG. 21). During the etching process, the photolithographic pattern on the upper insulating layer 317 may expose the upper insulating layer 317 over the backplate pad 630 and the diaphragm pad 610 so that a first contact hole 750 may be formed that exposes the backplate pad 630, and a second contact hole 770 that exposes the diaphragm pad 610.

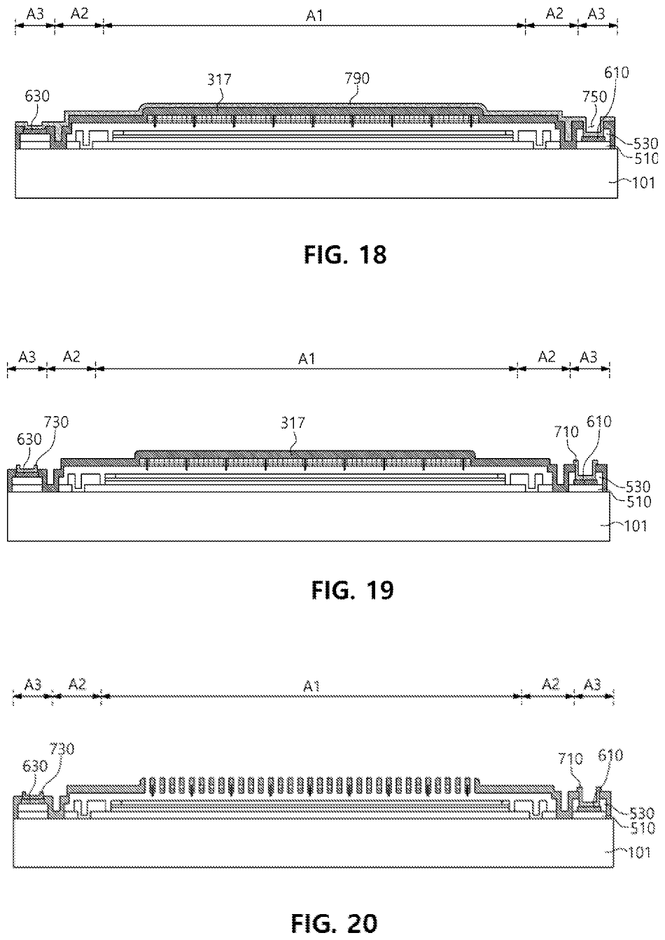

Then, a first electrode 710 is formed on the diaphragm pad 610, and a second electrode 730 is formed on the backplate pad 630. Referring to FIG. 18, for example, a conductive thin film 790 is blanket-deposited on the upper insulating film 317 and in the first contact hole 750 and the second contact hole 770. The thin film 790 may comprise a conductive metal film. After that, referring to FIG. 19, the thin film 790 is etched to form the first electrode 710 and the second electrode 730.

Thereafter, referring to FIG. 20, a plurality of through holes 211 may be formed by photolithographically patterning a photoresist on the upper insulating film 317, then sequentially etching the upper insulating film 317, the backplate 210, the first insulating film 450 and the upper electrode 430. As described above, the through holes 211 may function as passages for sound.

Then, referring to FIG. 21, a cavity 1011 may be formed in the substrate 101 below the diaphragm 110 by photolithographically patterning a photoresist on the backside of the substrate 101 and etching the substrate 101 in the bending area A1. One side or surface of the lower insulating film 510 is exposed through the cavity 1011. In addition, the lower insulating film 510 over the cavity 1011, the sacrificial layer 530 between the diaphragm 110 and the backplate 210, and the lower insulating film 510 and the sacrificial layer 530 between the anchor 130 and the chamber 313 are removed. To be specific, for example, when the lower insulating film 510 and the sacrificial layer 530 each comprise or consist essentially of silicon dioxide, etching the lower insulating film 510 and the sacrificial layer 530 may comprise passing an etchant such as hydrogen fluoride vapor through the cavity 1011, the vent hole 113, and the through holes 211. Alternatively, the lower insulating film 510 and the sacrificial layer 530 may be selectively wet etched using an aqueous HF solution. As a result, an air gap A may be formed between the diaphragm 110 and the backplate 210. The flow path of the etching fluid may be limited by the chamber 313 (e.g., when the chamber 313 comprises a material other than silicon dioxide).

The above detailed description is illustrative of the present disclosure. In addition, the above description shows and describes various embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiments describe various states for implementing the technical idea of the present disclosure, and various changes for specific application fields and/or uses of the present disclosure are possible. Accordingly, the detailed description of the present disclosure is not intended to limit the present disclosure to the disclosed embodiments.

What is claimed is:

1. A MEMS microphone structure, comprising:
a substrate having a cavity in a bending area;
a diaphragm on, in or over the cavity in the bending area;
an anchor on the substrate in a support area and configured to support the diaphragm;
a backplate spaced apart from the diaphragm;
an upper insulating film on the backplate;
a chamber on the substrate in the support area and configured to support the backplate;
a lower electrode below the diaphragm; and
an upper electrode between the diaphragm and the backplate.

2. The MEMS microphone structure of claim 1, wherein the upper electrode and the lower electrode comprise a conductive material.

3. The MEMS microphone structure of claim 1, further comprising:
a first insulating film having an upper surface in contact with the diaphragm and a lower surface in contact with the lower electrode; and
a second insulating film having an upper surface in contact with the backplate and a lower surface in contact with the upper electrode.

4. The MEMS microphone structure of claim 3, wherein the backplate, the second insulating film, and the upper electrode include a plurality of projection holes at positions corresponding to each other, and
the upper insulating layer includes a plurality of projections passing through the respective projection holes in the backplate, the second insulating film, and the upper electrode.

5. The MEMS microphone structure of claim 4, wherein each of the projections has a length or height greater than a total thickness of the backplate, the second insulating film, and the upper electrode.

6. A MEMS microphone structure, comprising:
a substrate having a cavity in a bending area;
a diaphragm on, in or over the cavity in the bending area;
an anchor on the substrate in a support area and configured to support the diaphragm;
a backplate spaced apart from the diaphragm, forming an air gap;
an upper insulating film on the backplate;
a chamber on the substrate in the support area and configured to support the backplate;
an upper electrode above the diaphragm; and
a lower electrode below than the diaphragm,
wherein the upper electrode and the lower electrode are in the bending area.

7. The MEMS microphone structure of claim 6, further comprising:
a first insulating film having an upper surface in contact with the diaphragm and a lower surface in contact with the lower electrode; and
a second insulating film having an upper surface in contact with the backplate and a lower surface in contact with the upper electrode,
wherein the diaphragm includes a plurality of vent holes spaced apart from each other, and
the backplate and the upper insulating film include a plurality of through holes spaced apart from each other.

8. The MEMS microphone structure of claim 6, further comprising:
a lower insulating film on the substrate in a peripheral area;
a diaphragm pad on the lower insulating film;
a sacrificial layer on the lower insulating film; and
a first electrode on the diaphragm pad and electrically connected to the diaphragm pad.

9. The MEMS microphone structure of claim 8, further comprising:
a backplate pad on the sacrificial layer; and
a second electrode on the backplate pad and electrically connected to the backplate pad.

10. The MEMS microphone structure of claim 6, wherein the anchor comprises:
a seating portion seated on the substrate in the support area;
an inner wall extending upward from the seating portion; and
an outer wall facing the inner wall and extending upward from the seating portion.

11. The MEMS microphone structure of claim 6, wherein the backplate, the second insulating film, and the upper electrode include a plurality of projection holes, at positions corresponding to each other, and
the upper insulating layer includes a plurality of projections passing through the respective projection holes of the backplate, the second insulating film, and the upper electrode.

12. A method of manufacturing a MEMS microphone structure, the method comprising:
forming a lower insulating film on a substrate;
forming a lower electrode on the lower insulating film in a bending area;
forming a first insulating film on the lower electrode;
forming a diaphragm on the first insulating film;
forming a sacrificial layer on the lower insulating film;
forming an upper electrode on the sacrificial layer in the bending area;
forming a second insulating film on the upper electrode; and
forming a backplate on the second insulating film.

13. The method of claim 12, wherein forming the lower electrode and forming the first insulating film comprise:
sequentially depositing a lower electrode layer and a first insulating layer on the lower insulating film; and
etching the lower electrode layer and the first insulating layer outside the bending area.

14. The method of claim 12, wherein forming the diaphragm comprises:
forming an anchor groove in the lower insulating film in a support area;
forming a first silicon layer on the lower insulating film, the lower electrode, and the first insulating film;
doping the first silicon layer with impurities; and
etching the first silicon layer to form the diaphragm and an anchor.

15. The method of claim 13, wherein forming the upper electrode and forming the second insulating film comprise:
sequentially depositing an upper electrode layer and a second insulating layer on the sacrificial layer; and
etching the upper electrode layer and the second insulating layer outside the bending area.

16. The method of claim 15, wherein forming the backplate comprises:
forming a second silicon layer on the sacrificial layer, the second insulating film, and the upper electrode;
doping the second silicon layer with impurities; and
etching the second silicon layer to form the backplate and a backplate pad.

17. The manufacturing method of claim 12, further comprising:
forming a cavity by etching the substrate in the bending area; and
removing the lower insulating film over the cavity.

18. A method of manufacturing a MEMS microphone structure, the method comprising:
forming a lower insulating film on a substrate;
forming a lower electrode on the lower insulating film and a first insulating film on the lower electrode in a bending area;
forming a diaphragm on the first insulating film;
forming a sacrificial layer on the lower insulating film;
forming an upper electrode on the sacrificial layer in the bending area;
forming a second insulating film on the upper electrode;
forming a backplate on the second insulating film; and
forming first to third overlapping projection holes through the upper electrode, the second insulating film and the backplate, and forming recesses or depressions in the sacrificial layer under the first to third projection holes;
forming an upper insulating film having projections passing through the first to third projection holes on the backplate.

19. The method of claim 18, wherein forming the upper insulating film comprises:
forming a chamber region by etching the lower insulating film and the sacrificial layer;
depositing an upper insulating layer on the sacrificial layer and in the chamber region; and
forming the upper insulating film on the backplate and a chamber of a support area by etching the upper insulating layer.
